(19) United States
(12) Patent Application Publication
(10) Pub. No.: US 2006/0202724 A1
(43) Pub. Date: Sep. 14, 2006

(54) Comparator circuit assembly, in particular for semiconductor components

(75) Inventor: Pramod Acharya, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/341,845

(22) Filed: Jan. 30, 2006

(30) Foreign Application Priority Data
Jan. 31, 2005 (DE) 10 2005 004 425.5

(51) Int. Cl. H03B 1/00

(52) U.S. Cl. 327/112

(57) ABSTRACT

The invention relates to a semi-conductor component with a comparator circuit assembly (1), as well as a comparator circuit assembly (1), in particular a comparator/receiver circuit assembly, comprising a first and second transistor (8, 9), whose control inputs are connected with each other, and a third transistor (10), to whose control input an input signal (VIN) is applied, and which is connected to the first transistor (8), and a fourth transistor (11), to whose control input a reference signal (VREFmod, VER) is applied, and which is connected to the second transistor (9), whereby the control input of the third transistor (10) is connected to the control inputs of the first and second transistor (8, 9) via a coupling device (22).

### CLAIM FOR PRIORITY

This application claims the benefit of priority of German Applicaton No. 10 2005 004 425.5, filed in the German language on Jan. 31, 2005, the contents of which are hereby incorporated by reference.

The invention relates to a comparator circuit assembly in terms of the pre-amble of claim 1, in particular a comparator/receiver circuit assembly, as well as a semi-conductor component with a corresponding circuit assembly.

In semi-conductor components, in particular for instance in memory components such as DRAMs (DRAM=Dynamic Random Access Memory and/or dynamic read-write memory), SRAMs (SRAM=Static Random Access Memory)—for instance based on CMOS technology—etc., etc., and/or for instance in corresponding integrated (analog and/or digital) computing circuits as well as other electrical circuits, so-called comparator/receiver circuit assemblies are often used.

A comparator/receiver circuit assembly serves to amplify a signal, for instance a pulse or clock signal, present at an input of the semi-conductor component.

Clock signals are used inside the semi-conductor component for the chronological co-ordination of the processing and/or relaying of data.

With conventional semi-conductor components a single clock signal (i.e. a so-called “single-ended” clock signal)—present on a single line—is generally used.

The data can then for instance in each case be relayed during the ascending pulse flank of the single clock signal (or alternatively for instance during the descending pulse flank of the single clock signal).

In addition there are already so-called DDR-components, in particular DDR-DRAMs (DDR-DRAM=Double Data Rate DRAM and/or DRAM with double data rate) available in state of the art technology.

With DDR components—instead of a single clock signal present on a single line (“single-ended” clock signal)—two differential, inversely equal clock signals present on two separate lines are used.

Every time, for instance when the first clock signal of the two clock signals changes its state from “high logic” (for instance a high voltage level) to “low logic” (for instance a low voltage level), the second clock signal—essentially simultaneously—changes its state from “low logic” to “high logic” (for instance from a low to a high voltage level).

Conversely, whenever the first clock signal changes its state from “low logic” (for instance a low voltage level) to “high logic” (for instance a high voltage level), the second clock signal (again essential simultaneously) changes its state from “high logic” to “low logic” (for instance from a high to a low voltage level).

In DDR components the data is usually relayed during the ascending flank of the first clock signal, as well as during the ascending flank of the second clock signal (and/or during the descending flank of the first clock signal, as well as during the descending flank of the second clock signal).

For this reason the relaying of data in a DDR component takes place more frequently and/or more quickly (in particular twice as frequently and/or twice as quickly), than in corresponding conventional components with a single and/or “single ended” clock signal, i.e. the data rate is higher, in particular twice as high, as in corresponding conventional components.

Conventional comparator/receiver circuit assemblies—for instance as used for amplifying clock signals—can for instance be constructed in the form of a differential amplifier with current-mirroring circuitry.

Frequently corresponding conventional comparator/receiver circuit assemblies are constructed in such a way that an input differential signal (for instance a differential clock signal) is changed into a “single-ended” signal.

Conventional comparator/receiver circuit assemblies have the disadvantage inter alia of being relatively sensitive to process, voltage and/or temperature variations, etc.—relatively high process, voltage and/or temperature variations can therefore affect the reliability of the corresponding comparator/receiver circuit assemblies.

The “Input Rise Time-Output Rise Time” skew (and/or the “Input Fall Time-Output Fall Time” skew can for instance be used as a nominal parameter for the reliability of comparator/receiver circuit assemblies.

The invention is aimed at making available a novel comparator circuit assembly, in particular a novel comparator/receiver circuit assembly, as well as a semi-conductor component comprising such a circuit assembly.

It achieves these and other aims by means of the subject matters of claims 1 and 18.

Advantageous further developments of the invention are listed in the subsidiary claims.

In terms of one aspect of the invention, a comparator circuit assembly is made available, comprising a first and second transistor, whose control inputs are connected with each other, and a third transistor, to whose control input an input signal (VIN) is applied, and which is connected to the first transistor, and a fourth transistor, to whose control input a reference signal (VREFmod, VER) is applied, and which is connected to the second transistor, whereby the control input of the third transistor is connected to the control inputs of the first and second transistor via a coupling device.

Advantageously the coupling device comprises a capacitor.

In terms of an advantageous aspect of the invention the comparator circuit assembly comprises a further transistor, to whose control input the input signal (VIN) is applied, and which transistor is connected with the control inputs of the first and second transistor.

It is particularly advantageous for the comparator circuit assembly to comprise a further transistor, to whose control input the input signal (VIN) is applied, and which transistor is connected with the third and fourth transistor.

Below the invention is more closely described by means of an embodiment example and the attached illustration. In the illustration:

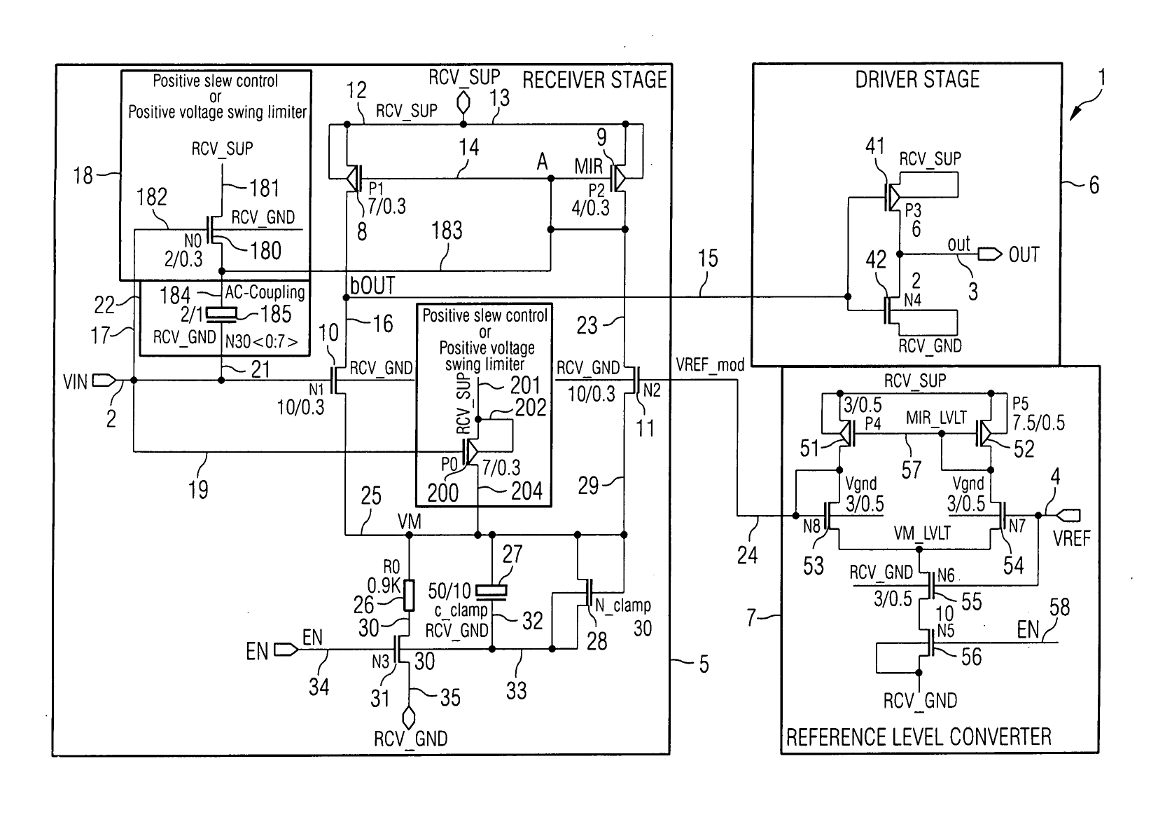

FIG. 1 shows a schematic representation of a comparator circuit assembly, in particular a comparator/receiver circuit assembly in terms of an embodiment example of the present invention.

In FIG. 1 a schematic representation of a comparator, in particular a comparator/receiver circuit assembly 1 in terms of an embodiment example of the present invention is shown.

The circuit assembly 1 can for instance be installed into a semi-conductor component, for instance into a DRAM memory component (DRAM=Dynamic Random Access Memory and/or dynamic read/write memory)—based on CMOS technology—, an SRAM memory component (SRAM=Static Random Access Memory), etc., etc., and/or into any suitable integrated (analog and/or digital) computing circuit, etc., and/or can—in general terms—form part of any other suitable electrical circuit.

The DRAM memory component can for instance be a DDR-DRAM (DDR-DRAM=Double Data Rate DRAM and/or a DRAM with double data rate).

This component comprises two input clock connections (for instance corresponding component pads connected with corresponding pins), whereby a first clock signal clk—derived from an external clock signal generator, i.e. coming from the outside—is applied to the first clock connection—and a second clock signal bclk—also generated by the external clock signal generator—is applied to the second clock connection.

The two clock signals clk and bclk can for instance be so-called differential, i.e. inversely equal clock signals: every time for instance that the first clock signal clk changes from a “high logic” state to a “low logic” state, the second clock signal bclk—essentially simultaneously—changes its state from “low logic” to “high logic”.

Conversely, every time that the first clock signal clk changes from a “low logic” to a “high logic”, the second clock signal bclk—essentially simultaneously—changes its state from “high logic” to “low logic”.

The comparator/receiver circuit assembly 1 serves to amplify a signal VIN present on a line 2, and makes available an output signal OUT—derived from the signal VIN—at a corresponding output line 3.

The input signal can for instance be the above clock signal clk or bclk, or any other suitable signal (externally present at a corresponding pin of the semi-conductor component, or made internally available in the semi-conductor component), for instance a data or control signal applied to a data or control input of the semi-conductor component.

In particular the comparator/receiver circuit assembly 1 serves to amplify a high-frequency “low swing” signal present at line 2: If the voltage level of the signal VIN lies above the voltage level of a reference signal VREF present on a line 4 (for instance VDD/2, for instance 0.75V)—and/or as is more closely described further below, of a reference signal VREFmod—a corresponding “positive” swing should be detected (by means of a corresponding output signal OUT which is then “high logic” (or alternatively: “low logic”)). Conversely, if the voltage level of the signal VIN lies below the voltage level of the reference signal VREF present on the line 4 (for instance VDD/2, for instance 0.75V)—and/or of the reference signal VREFmod—, a corresponding “negative” swing should be detected (by means of a corresponding output signal OUT which is then “low logic” (or alternatively: “high logic”)).

As is apparent from FIG. 1, the comparator/receiver circuit assembly 1 comprises an input stage 5 (“Receiver Stage”), an output stage 6 (“Driver Stage”), and a reference level converter stage 7 (“Reference Level Converter”).

Several transistors 8, 9, 10, 11 for signal amplifying are provided in the input stage 5 (here: corresponding n-channel MOSFETs 10, 11, and corresponding p-channel MOSFETs 8, 9, wherein the p-channel MOSFET 9 operates as current mirror, and the p-channel MOSFET 8 as load).

The sources of the p-channel MOSFET 8, 9 are connected with the supply voltage RCV_SUP via lines 12, 13 (whereby RCV_SUP could for instance amount to 1.5 V).

The gate of the p-channel MOSFET 8 is connected with the gate of the p-channel MOSFET 9 via a line 14.

The drain of the p-channel MOSFET 8 is connected with the output stage 6 via a line 15, and with the drain of the n-channel MOSFET 10 via a line 16.

The gate of the n-channel MOSFET 10 is connected with the above (input) line 2, as well as—as is more closely described below—with a swing/slew limiter circuit 18 via a line 17, with a further swing/slew limiter circuit 20 via a line 19, and with an AC coupling device via a line 21.

As is further apparent from FIG. 1, the drain of the p-channel MOSFET 9 is connected with the drain of the n-channel MOSFET 11 via a line 23.

The gate of the n-channel MOSFET 11 is connected via a line 24 with the above reference level converter stage 7.

The source of the n-channel MOSFET 10 is connected via a line 25 with a resistor 26, a capacitor 27, and the drain of an n-channel MOSFET 28.

In correspondingly similar fashion the source of the n-channel MOSFET 11 is also connected—via a line 29—with the resistor 26, the capacitor 27, and the drain of the n-channel MOSFET 28.

The resistor 26 is connected via a line 30 with the drain of an n-channel MOSFET 31.

The gate of the n-channel MOSFET 31 is connected via a line 32 with the capacitor 27, and via a line 33 with the source of the n-channel MOSFET 28, and is connected with a line 34 to which an enable signal (EN signal) can be applied.

The source of the n-channel MOSFET 31 is connected via a line 35 with the ground potential (RCV_GND).

By means of the enable signal (EN signal) applied to line 34, correspondingly controlling the n-channel MOSFET 31, the path between the supply voltage RCV_SUP, and the ground potential (RCV_GND) in the comparator/receiver circuit assembly 1 can—depending on the state of the enable signals—be either blocked or opened (whereby the comparator/receiver circuit assembly 1 as a whole is brought into either a disabled or an enabled state).

As is further apparent from FIG. 1, the output-stage 6 of the comparator/receiver circuit assembly 1 comprises two transistors 41, 42 (and in fact an n-channel MOSFET 42 and a p-channel MOSFET 41).

The gates of the n-channel and the p-channel MOSFET 41, 42 are connected with the above line 15 (and thereby with the input stage 5).

The source of the p-channel MOSFET 41 is connected with the above supply voltage (RCV_SUP) and the source of the n-channel MOSFET 42 with the ground (RCV_GND).

The drains of the n-channel and of the p-channel MOSFET 41, 42 are connected with the above (output) line 3, at which—as explained above—the output signal OUT made available by the comparator/receiver circuit assembly 1 can be detected.

As is further apparent from FIG. 1, the reference level converter stage 7 of the comparator/receiver circuit assembly 1 comprises a plurality of transistors 51, 52, 53, 54, 55, 56 (and in fact a plurality of n-channel MOSFETs 53, 54, 55, 56, and a plurality of p-channel MOSFETs 51, 52).

The sources of the p-channel MOSFETs 51, 52 are connected with the above supply voltage (RCV_SUP).

The gate of the p-channel MOSFET 51 is connected with the gate of the p-channel MOSFET 52 via a line 57.

The drain of the p-channel MOSFET 51 is connected with the drain of the n-channel MOSFET 53 and the drain of the p-channel MOSFET 52 is connected with the drain of the n-channel MOSFET 54.

The sources of the n-channel MOSFET 53, 54 are connected with the drain of the n-channel MOSFET 55, whose source is connected with the drain of the n-channel MOSFET 56.

The source of the n-channel MOSFET 56 is connected with the ground potential (RCV_GND) and the gate of the n-channel MOSFET 56 is connected with a line 58, to which the above enable signal (EN signal)—or any other suitable signal—is applied.

The gate of the n-channel MOSFET 55 and the gate of the n-channel MOSFET 54 are connected with the above line 4 (at which, as described above, the above reference signal VREF is present).

With the help of the reference level converter stage 7 the reference signal VREF—which may be subject to correspondingly strong fluctuations (for instance up to 5%)—may be converted into a modified reference signal VREFmod—emitted onto line 24 connected with the gate of the n-channel MOSFET 53 (and/or with its drain, and the drain of the p-channel MOSFET 51)—which signal is only subject to minor fluctuations (and for instance exhibits a slightly higher voltage level than the reference signal VREF (for instance a voltage level higher by about 100 mV), such that the input signal VIN—internally—is not exactly compared with the reference signal VREF, but with a slightly higher reference signal VREFmod).

The circuit section—serving to enable and/or disable the input stage 5 and/or the comparator/receiver circuit assembly 1, in particular for instance comprising the n-channel MOSFET 31—and/or the circuit section—serving as signal amplifier, here: comprising the n-channel MOSFETs 10, 11, and the p-channel MOSFETs 8, 9—can be essentially correspondingly similarly or identically constructed and can operate like circuit sections of conventional input stages and/or comparator/receiver circuit assemblies executing corresponding functions (except inter alia for those differences more closely described below and/or further differences e.g. evident from FIG. 1):

In particular a “low logic” (or alternatively: a “high logic”) signal bOUT is emitted to the above line 15 by the above circuit section serving as a signal amplifier whenever the voltage level of the signal VIN present on line 2 lies above the above-mentioned voltage level of the above-mentioned reference signal VREF (and/or VREFmod), which results in the signal OUT emitted by the output stage onto line 3 taking on a “high logic” (or alternatively: a “low logic”) state.

Conversely a “high logic” (or alternatively: “low logic”) signal bOUT is emitted onto the above line 15 by the above circuit section serving as a signal amplifier, whenever the voltage level of the signal VIN present on line 2 lies below the voltage level of the above-mentioned reference signal VREF (and/or VREFmod), which results in the signal OUT emitted by the output stage onto line 3 taking on a “low logic” (or alternatively: “high logic”) state.

As is apparent from FIG. 1, the above (first) swing/slew limiter circuit 18 in the comparator/receiver circuit assembly 1—which serves to limit positive swings—comprises a transistor (here: an n-channel MOSFET 180), whose gate is connected with the (input) line 2 (and thereby also with the gate of the n-channel MOSFET 10, and the above lines 19, 21) via the above line 17, and via a line 182 with the ground potential (RCV_GND).

The drain of the n-channel MOSFET 180 is connected with the above supply voltage (RCV_SUP) via a line 181.

In addition, the source of the n-channel MOSFET 180 is connected with the above AC coupling device 22 via a line 184, and via a line 183 with the gates of the p-channel MOSFETs 8, 9, and with the drains of the p- and/or n-channel MOSFETs 9, 11.

The AC coupling device 22 comprises a capacitor 185, which is connected with the swing/slew limiter circuit 18 (in particular with the source of the n-channel MOSFET 180) via the line 184, and via the line 183 with the gates of the p-channel MOSFETs 8, 9, and with the drains of the p- and/or n-channel MOSFETs 9, 11, and via the line 21 with the (input) line 2 (and the gate of the n-channel MOSFET 10).

The (further) swing/slew limiter circuit 20—which serves to limit negative swings—comprises a transistor (here: a p-channel MOSFET 200), whose gate is connected with the (input) line 2 (and thereby also with the gate of the n-channel MOSFET 10, and the above lines 17, 21) via the above line 19, and via a line 202 with a line 201, which is connected with the source of the p-channel MOSFET 200, and with the above supply voltage (RCV_SUP).

In addition the drain of the p-channel MOSFET 200 is connected with the sources of the n-channel MOSFETs 10, 11 via a line 204, and with the resistor 26, the capacitor 27, and the drain of the n-channel MOSFET 28.

By means of the above-mentioned coupling of the (input) line 2 via the AC coupling device 22, in particular the capacitor 185, with an internal circuit assembly nodal point A, which controls the gates of the p-channel MOSFETs 8, 9 (i.e. the p-channel load), the switching performance of the p-channel MOSFETs 8, 9 can be improved, and/or the signal response times achieved by the comparator/receiver circuit assembly 1 can—where appropriate substantially—be improved (as by the AC coupling device 22 the information comprised in the input signal VIN is—in advance—switched to the nodal point A, such that the load transistor 8 is switched-over more quickly).

In addition, by the coupling achieved by means of the AC coupling device 22 variations in DC switch-over levels due to process, voltage and/or temperature fluctuations can be—partially at least—compensated for.

To prevent the comparator/receiver circuit assembly 1 from switching (over) incorrectly during particularly rapid changes in the voltage level of the input signal VIN (“ringing”)—occurring frequently in high frequency applications—, and/or at particularly high or low input signal voltage levels (in particular when the voltage level of the input signal VIN lies particularly far above or below the voltage level of the reference signal VREF and/or VREFmod), the above swing/slew limiter circuits 18, 20 are—additionally—provided in the comparator/receiver circuit assembly 1 (in particular to prevent a wrong switching over otherwise potentially provoked in the above circumstances by the AC coupling device 22, even though the input signal is still above (or under) the reference signal VREFmod).

For the swing/slew limitation to be achieved by the swing/slew limiter circuits 18, 20—as is apparent from FIG. 1—a (relative weak) n-channel is used (cf. in particular for instance the n-channel MOSFET 180), which is switched by/connected via the above (relatively strong) p-channel load (in particular the p-channel MOSFETs 8, 9), and further a (relative weak) p-channel (cf. in particular for instance the p-channel MOSFET 200), in order to control the tail voltage at the source coupling point VM of the comparator/receiver circuit assembly 1.

As the gates of the n-channel MOSFET 180 and of the p-channel MOSFET 200 are controlled by the input signal VIN, the n-channel MOSFET 180 and the p-channel MOSFET 200 each operate as “voltage controlled resistors”: When the voltage level of the input signal VIN rises above corresponding values (and/or rises too strongly and/or too fast) or falls below corresponding values (and/or falls too strongly and/or too fast), the n- and/or p-channel MOSFET 180, 200 is in each case correspondingly (more strongly) switched on, thereby counteracting the negative effects provoked by the AC coupling device 22 caused by the input signal VIN rising and/or falling (too strongly).

With—non-critical—signal level changes (i.e. with relatively slow changes in the voltage levels of the input signal VIN, and/or voltage levels of the input signals VIN lying relatively low above or below the voltage level of the reference signal VREF and/or VREFmod) the gate drive of the n-channel MOSFET 180 and of the p-channel MOSFET 200 is relatively small, and has no or only a minor effect on the operation of the comparator/receiver circuit assembly 1.

As is apparent from FIG. 1 (and already described above) in the comparator/receiver circuit assembly 1 a capacitive element—namely the above capacitor 27—is interconnected (and in fact by means of the transistor 31) between the source coupling point VM, and the ground potential (RCV_GND). As the voltage across the capacitor 27 is unable to change abruptly, the voltage at the source coupling point VM is unable to follow a change in the state of the voltage level of the input signal (VIN) abruptly. This has the effect that, with a change in the state of the voltage level of the input signal (VIN) a higher gate source voltage can be achieved at the n-channel MOSFET 10—and thereby a quicker switching over—than with conventional comparator/receiver circuit assemblies.

In contrast with conventional comparator/receiver circuit assemblies, the comparator/receiver circuit assembly 1 shown in FIG. 1 does not necessarily need to show a symmetrical configuration, but can also show an asymmetrical configuration; in particular the p-channel loads (and/or the p-channel MOSFET 8 of the output side, and the p-channel MOSFET 9 of the current-mirroring side)—as opposed to conventional comparator/receiver circuit assemblies—are not symmetrical, but asymmetrical, and/or not equal in size (in particular for instance differing in size by more than 20%, for example by more than 40%).

In the comparator/receiver circuit assembly 1 shown in FIG. 1, in comparison with conventional comparator/receiver circuit assemblies, the (relatively small) signal impedance of the current-mirroring side—connected with the p-channel MOSFET 9—is increased, with the result that the output side can be more strongly driven by the larger swings of the p-channel MOSFET 8 caused by this increase.

1. A comparator circuit assembly (1), in particular a comparator/receiver circuit assembly, comprising a first and second transistor (8, 9), whose control inputs are connected with each other, and a third transistor (10), to whose control input an input signal (VIN) is applied, and which is connected to the first transistor (8), and a fourth transistor (11), to whose control input a reference signal (VREFmod, VER) is applied, and which is connected to the second transistor (9), whereby the control input of the third transistor (10) is connected to the control inputs of the first and second transistor (8, 9) via a coupling device (22).

2. A comparator circuit assembly (1) according to claim 1, in which the coupling device (22) comprises a capacitor (185).

3. A comparator circuit assembly (1) according to claim 1, comprising a control device (18) for limiting effects caused by the coupling device (22) when big differences between the input signal (VIN) and the reference signal (VREFmod, VER) occur.

4. A comparator circuit assembly (1) according to claim 3, wherein the control device (18) comprises a further transistor (180), to whose control input the input signal (VIN) is applied, and which transistor (180) is connected with the control inputs of the first and second transistor (8, 9).

5. A comparator circuit assembly (1) according to claim 4, in which the further transistor (180) is additionally connected with the coupling device (22).

6. A comparator circuit assembly (1) according to claim 4, in which a supply voltage (RCV_SUP) is applied to the first, second and further transistor (8, 9, 180).

7. A comparator circuit assembly (1) according to claim 3, comprising a further control device (20) for limiting effects caused by the coupling device (22) when big differences between the input signal (VIN) and the reference signal (VREFmod, VER) occur.

8. A comparator circuit assembly (1) according to claim 7, wherein the control device (18) limits the effects caused by the coupling device (22) when the level of the input signal (VIN) is higher than the level of the reference signal (VREFmod, VER), and the further control device (20) limits the effects caused by the coupling device (22) when the level of the input signal (VIN) is lower than the level of the reference signal (VREFmod, VER).

9. A comparator circuit assembly (1) according to claim 7, wherein the further control device (20) comprises a further transistor (200), to whose control input the input signal (VIN) is applied, and which transistor (200) is connected with the control inputs of the third and fourth transistor (10, 11).

10. A comparator circuit assembly (1) according to claim 9, in which the supply voltage (RCV_SUP) is applied to the further transistor (200).

11. A comparator circuit assembly (1) according to claim 1, in which the third and fourth transistor (10, 11) are connected with a capacitive component (27).

12. A comparator circuit assembly (1) according to claim 11, in which the further transistor (200) is connected with the capacitive component (27).

13. A comparator circuit assembly (1) according to claim 1, in which the first and second transistor (8, 9) are field effect transistors.

14. A comparator circuit assembly (1) according to claim 13, in which the first and second transistor (8, 9) are p-channel field effect transistors.

15. A comparator circuit assembly (1) according to claim 4, in which the further transistor (180) is a field effect transistor.

16. A comparator circuit assembly (1) according to claim 15, in which the further transistor (180) is an n-channel field effect transistor.

17. A comparator circuit assembly (1) according to claim 1, in which the third and fourth transistor (10, 11) are field effect transistors.

18. A comparator circuit assembly (1) according to claim 17, in which the third and fourth transistor (10, 11) are n-channel field effect transistors.

19. A comparator circuit assembly (1) according to claim 9, in which the further transistor (200) is a field effect transistor.

20. A comparator circuit assembly (1) according to claim 19, in which the further transistor (200) is a p-channel field effect transistor.

21. A semi-conductor component, with a comparator circuit assembly (1) according to claim 1.

22. A semi-conductor component according to claim 21, in which the input signal (VIN) is an input signal of the semi-conductor component.
